(19) United States
(12) Patent Application Publication
(10) Pub. No.: US 2007/0184565 A1
(43) Pub. Date: Aug. 9, 2007

(54) TEST PATTERN AND METHOD FOR MEASURING SILICON ETCHING DEPTH

(75) Inventors: Hwan-Shik PARK, Seoul (KR); Sung-Gon KIM, Gyeonggi-do (KR); Chung-Sam JUN, Gyeonggi-do (KR); Kye-Weon KIM, Gyeonggi-do (KR); Jang-Ik PARK, Gyeonggi-do (KR); Won-Kwan SONG, Daegu Metropolitan (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/566,637

(22) Filed: Dec. 4, 2006

(30) Foreign Application Priority Data
Feb. 8, 2006 (KR) 2006-12182

(51) Int. Cl. H01L 21/66

(52) U.S. Cl. 438/14; 438/16

(57) ABSTRACT

Embodiments of a test pattern and a method for measuring silicon etching depth are provided. After a contact-hole forming process, an optical critical dimension (OCD) is measured with respect to a test pattern formed on a semiconductor chip, so that the silicon etching depth may be analyzed in real time. Critical dimensions of contact holes in the actual working cells of the semiconductor circuit would then coincide with the OCD measurement of the contact holes of the test pattern. Consequently, etching conditions for forming a contact hole may be controlled in real time, and thus a yield of a semiconductor can be effectively improved.

### CROSS-REFERENCE TO RELATED APPLICATIONS

This U.S. non-provisional patent application claims priority under 35 U.S.C. § 119 of Korean Patent Application No. 10-2006-12182, filed on Feb. 8, 2006, the entire contents of which are hereby incorporated by reference.

### BACKGROUND

The embodiments disclosed herein relate to a method for testing a contact of a semiconductor memory device, and more particularly, to a test pattern for measuring an etching depth of silicon etched in a contact-hole forming process, and a method for measuring a silicon etching depth using the test pattern.

In fabricating a semiconductor, one of the most important factors to manufacture a small chip is a miniaturized contact hole. Therefore, as semiconductor sizes decrease, dimensions of the contact hole that provides an electrical contact with respect to silicon also decrease. And a contact process margin for an electrical connection between a storage node and a source/drain region of a transistor is increasingly limited. The limitations in a design rule make a contact-hole forming process very difficult, and can be the cause of many defects in the contact-hole forming process.

An example of an etching process for forming a contact hole includes a self-aligned contact (SAC) etching process using a difference in etch selectivity between layers. In general, the SAC process is used mainly to ensure a photo misalign margin in a contact-hole forming process of a highly-integrated semiconductor device. The SAC process employs a technology such as an inductive-coupled plasma (ICP), a transformer coupled plasma (TCP), a surface wave plasma (SWP), a double ring magnetron (DRM), and the like. Also, in the SAC process, a gas such as C₃F₈, C₄F₈, CO or the like having a high carbon/fluorine (C/F) ratio is used to generate a large number of carbon polymers necessary for increasing selectivity with respect to silicon nitride (SiN). However, the aforementioned contact-hole forming process of the highly-integrated semiconductor device is problematic in that the quality of the device is greatly affected even by fine changes in etching conditions. To prevent this problem, a method for overetching silicon to a predetermined extent in the contact-hole forming process may be used.

However, defections may occur in forming a contact hole for several reasons during a process of mass-manufacturing semiconductor devices. For example, a contact hole may not be opened, or may be only opened insufficiently, or silicon may be excessively etched, which causes a resistance defect in the contact hole. For this reason, to prevent the defects, it is very important to accurately measure the silicon etching depth after the contact-hole forming process.

The most general method for measuring the silicon etching depth is cutting a wafer and directly checking a vertical profile of the wafer during a process of manufacturing a semiconductor device. However, this method is disadvantageous in that wafer loss occurs and it takes a long time to check whether or not the contact is opened. Particularly, since this method is not performed in real time, there are always possibilities that the wafers being processed while the etching depth is being measured are defective.

### SUMMARY

Embodiments provide a test pattern for measuring the silicon etching depth in real time after a contact process, and a method for measuring the silicon etching depth using the same.

Embodiments provide methods for measuring silicon etching depths, including performing a contact-hole forming process with respect to a plurality of semiconductor chips, each including a test pattern; measuring an OCD (optical critical dimension) from the test pattern; and analyzing a distribution of silicon etching depths of a wafer including the semiconductor chips on the basis of the measured OCD.

In some embodiments, etching conditions for the contact-hole forming process are controlled on the basis of the analyzed distribution of the silicon etching depths.

In other embodiments, the test pattern is a TEG (test element group) designated to one region of each semiconductor chip.

In still other embodiments, the contact-hole forming process is performed so that a first type contact hole for an actual cell, and one or more second type contact holes for the test pattern are formed in each of the semiconductor chips.

In yet other embodiments, the second type contact holes have the same diameter.

In still other embodiments, the second type contact hole is spaced apart from the adjacent first and second type contact holes at the same distance.

In further embodiments, the test pattern formed has a ratio of 0.5<c/a<3, where c represents the diameter of the second type contact hole, and a represents the distance between the adjacent first or second type contact hole.

In still further embodiments, the OCD is measured from the second type contact hole.

In even further embodiments, the OCD includes a diameter of the second type contact hole, a thickness of an oxide formed at a side of the second type contact hole, and an etching depth of silicon etched at a lower side of the contact hole.

In yet further embodiments, the OCD measured from the second type contact hole coincides with an OCD of the first type contact hole.

In some embodiment, the OCD is measured in-line during the chip manufacturing process.

In other embodiment, the distribution of the silicon etching depths is analyzed in real time.

In other embodiments of the present invention, test patterns for measuring a silicon etching depth include a first region in which a first type contact hole for an actual cell is formed through a contact-hole forming process; and a second region in which one or more second type contact holes are formed through the contact-hole forming process, wherein, after the contact-hole forming process, an OCD (optical critical dimension) is measured from the second type contact holes, and the measured OCD coincides with an OCD of the first type contact hole. The second type contact hole has a simpler structure than the first type contact hole. The simpler structure of the second type contact hole is adapted to an OCD (optical critical dimension) measurement wherein critical dimensions of the first type contact hole coincide with the OCD measurement of the second type contact hole.

In some embodiments, the second region is a TEG (test element group) for testing characteristics of the first type contact hole.

In other embodiments, the second type contact holes have the same diameter.

In still other embodiments, the second type contact hole is spaced apart from the adjacent first and second type contact holes at the same distance.

In even other embodiments, the test pattern has a ratio of 0.5<c/a<3, where c represents the diameter of the second type contact hole, and a represents the distance between the adjacent first or second type contact hole.

In yet other embodiment, the OCD includes a diameter of the second type contact hole, a thickness of an oxide formed at a side of the second type contact hole, and an etching depth of silicon etched at a lower portion of the contact hole.

In further embodiments, the OCD is measured in-line.

### BRIEF DESCRIPTION OF THE FIGURES

The accompanying figures are included to provide a further understanding of the present invention, and are incorporated in and constitute a part of this specification. The drawings illustrate exemplary embodiments and, together with the description, serve to explain principles of the present invention. In the figures:

FIG. 1 is a structural view of a test pattern for measuring a silicon etching depth according to an embodiment;

FIGS. 2 and 3 are vertical cross-sectional views illustrating structures of contact holes placed on lines A-B and C-D of FIG. 1, respectively;

FIG. 4 is a vertical cross-sectional view illustrating a detailed structure of a test region of FIG. 3;

FIG. 5 is a flow chart of a method for measuring a silicon etching depth according to an embodiment; and

FIGS. 6 through 8 are views showing analysis result of a silicon etching depth of a contact hole for a test, which is measured after a contact-hole forming process.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

Hereinafter, an exemplary embodiment of the present invention will be described in conjunction with the accompanying drawings.

In a test pattern and a method for measuring a silicon etching depth according to an embodiment, an optical critical dimension (OCD) of a test pattern formed on each semiconductor chip of a wafer may be measured to analyze a silicon etching depth in real time after a contact-hole forming process. Consequently, etching conditions for forming a contact hole are controlled in real time to improve semiconductor yield. A detailed description will now be described.

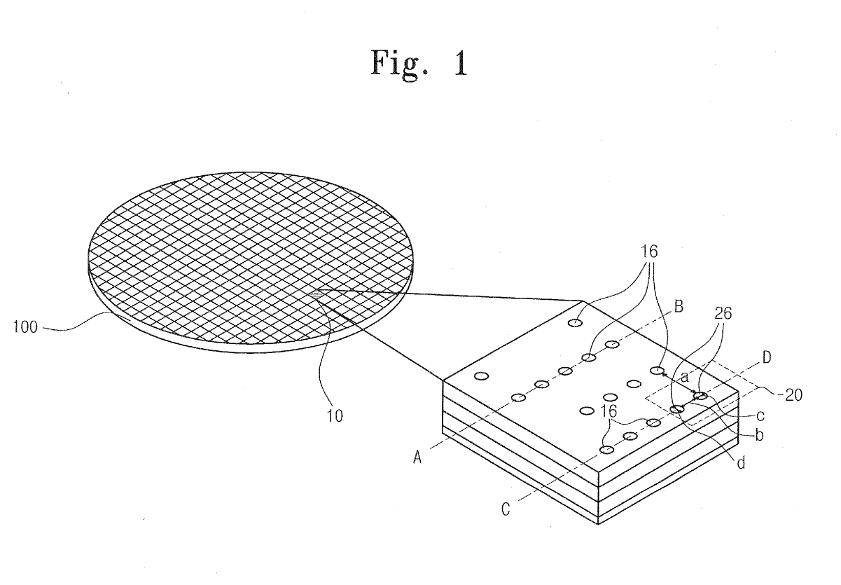

FIG. 1 is a structural view of a test pattern 20 for measuring a silicon etching depth according to an embodiment.

Referring to FIG. 1, a plurality of semiconductor chips are formed on a semiconductor wafer 100, and each semiconductor chip 10 is divided into a main region and a test region. A plurality of cells of the plurality of semiconductor chips 10 are formed by semiconductor thin film processes. The test region includes a test pattern 20 of measuring elements or test elements for testing characteristics of the cells or integrated circuits formed in the main region. The test pattern is generally called a test element group (TEG).

In the present embodiment, after the contact-hole forming process, a silicon etching depth is measured in-line and in real time during semiconductor manufacturing processes. The silicon etching depth is measured with respect to the test pattern formed in each semiconductor chip 10. Measuring the silicon etching depth is performed by an optical critical dimension (OCD) measuring device.

Because the silicon etching depth is measured in real time, the etching conditions for forming a contact hole may be controlled in real time.

To measure the silicon etching depth, the OCD measuring device generates light of multiple wavelengths using a white light source. The light is emitted onto a substrate of the semiconductor chip 10 that includes a test pattern 20. Next, light reflected from the substrate is detected by a spectrometer provided to the OCD measuring device.

The OCD measuring device includes a beam splitter so that the generated light is split according to wavelength. Accordingly, the spectrometer measures reflectivity as a function of wavelength. By using the reflectivity measured this way, a critical dimension of a pattern formed on the substrate can be measured. An exemplary configuration of the OCD measuring device that is applicable to the present embodiment is disclosed in Korean Patent Laid-Open Publication No. 10-2005-0068011, and U.S. Patent Laid-Open Publication No. US2005/0140988, both incorporated by reference in their entirety.

In the present embodiment, the reflectivity of the test pattern 20 formed on each semiconductor chip 10 may be measured by the aforementioned OCD measuring device to measure the amount of silicon being etched during a contact-hole forming process, or in other words, an etching depth of silicon being etched during the process. The measured silicon etching depth is critical information to determine whether or not a contact hole is opened correctly.

Because measuring the silicon etching depth is optically performed, wafer loss does not occur. Also, the etching depth is measured in-line with process equipment and in real time so that etching parameters of wafers being processed are controlled in real time, contributing to effective improvement of a yield.

The detailed construction of the test pattern 20 according to the present embodiment will now be described.

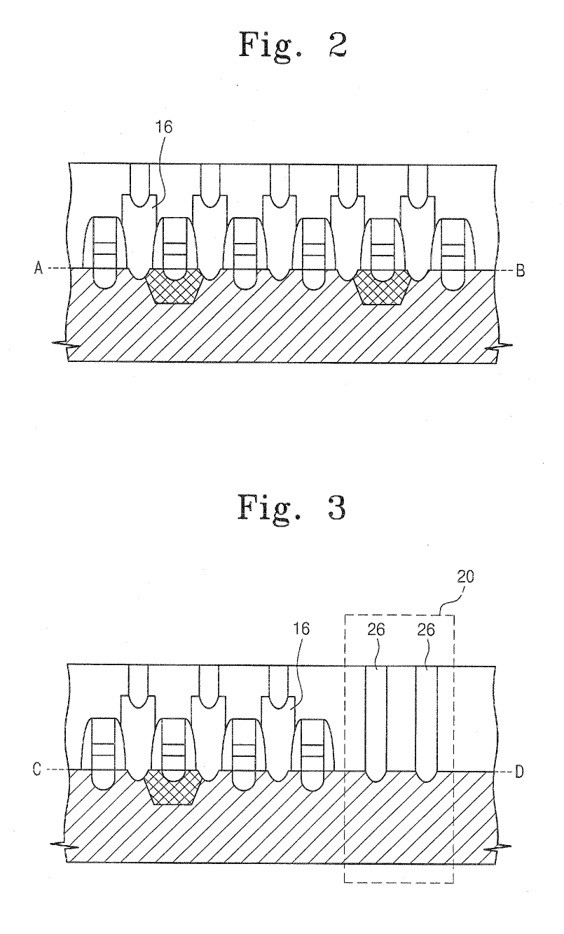

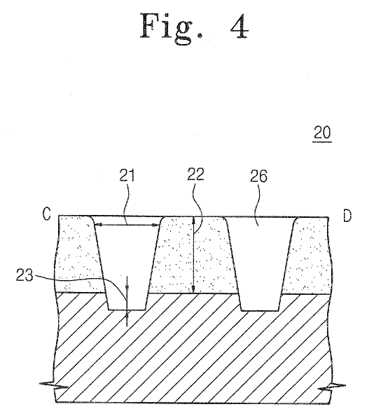

FIGS. 2 and 3 are vertical cross-sectional views illustrating structures of contact holes placed on lines A-B and C-D of FIG. 1, respectively. In FIG. 2, structures of contact holes 16 of actual cells, which are disposed on the line A-B of FIG. 1, are illustrated. In FIG. 3, structures of contact holes 26 of the test pattern 20 disposed on the line C-D of FIG. 1 are illustrated.

Referring to FIG. 2, a cross-section of the actual cell formed on the semiconductor chip 10 has a complicated structure, and arrangements of contact holes 16 are irregular. For example, the contact holes 16 may have a radius that changes discontinuously with depth, or otherwise may have a sidewall that is rough and irregular. Examples are shown in FIGS. 2 and 3. In any case, the contact holes may not have a simple cylindrical or conical shape. Because of this irregularity, it is virtually impossible to measure an OCD. Therefore, the present embodiment provides a test pattern 20 (FIG. 3) having a simple and regular structure, which is suitable for OCD measuring. A simple and regularly structured contact hole 26 includes those that have a continuously changing or constant radius with depth, or those with sidewalls that are smooth and regular. For example, a simple and regular cylindrical or conical shaped hole may be the contact hole 26. FIG. 3 shows an embodiment wherein the contact hole 26 has a simple cylindrical shape with smooth sidewalls and a constant radius. FIG. 4 shows an embodiment wherein the contact hole 26 has a simple conical shape with smooth sidewalls and a continuously changing radius 21.

The test pattern 20 is formed in one region of a memory chip 10 (preferably, in an edge region of the semiconductor chip 10) on which the actual cells are formed.

Referring to FIG. 3, a cross-sectional structure of the test pattern 20 according to the present embodiment is simple, and the pattern 20 includes contact holes 26 arranged regularly. As illustrated in FIG. 3, when one region of the semiconductor chip 10 on which actual memory cells are formed is designated as the test region 20, the contact hole 26 for a test (hereinafter, referred to as a test contact hole) may be formed adjacent to the contact hole 16 of the actual cell.

Although the test pattern formed on the memory chip 10 includes two test contact holes 26 in FIG. 3, this is merely an example of the present invention, and the number of test contact holes 26 of the test pattern 20 may be adjusted by those skilled in the art. For example, the test pattern 20 may be formed on an entire surface of a wafer (i.e., a TEG wafer), or may be formed on some of a plurality of semiconductor chips of a wafer 100 for device manufacturing. Also, the test pattern 20 may be formed on every semiconductor chip of the wafer 100 for device manufacturing like in the present embodiment, or all chips in a row of the wafer 100 for device manufacturing may be constructed as chips for a test pattern. The number of chips for a test disposed within the wafer 100 may be controlled with regard to the test time or productivity.

FIG. 4 is a vertical cross-sectional view of a detailed structure of the test region 20 of FIG. 3, illustrating factors used to measure an OCD.

Two test contact holes 26 formed on silicon (i.e., a region indicated by slant lines in the drawing) are illustrated. The number of test contact holes 26 may be controlled by those skilled in the art. Critical dimensions measured by the OCD measuring device according to the present embodiment may include an upper length 21 of the test contact hole 26 (i.e., a diameter of the test contact hole 26), a thickness 22 of an oxide, an etching depth 23 of silicon, and the like. Of those dimensions, the silicon etching depth 23 may serve as a criterion in determining whether or not the contact hole is opened.

Referring to the embodiment of FIG. 1, upper lengths (c, d) of the test contact holes 26 (i.e., diameters of the test contact holes 26) are the same, that is c=d. Also, distances (a, b) between the contact hole 26 and adjacent contact holes 16 and 26 are the same, that is a=b. In a preferred case, a ratio of the diameter (c) of the contact hole 26 to the distance (a) between the contact hole 26 and the adjacent contact hole is defined by Equation (1) below.

0.5<c/α<3 (1)

A method for measuring a silicon etching depth using the test pattern 20 designed as mentioned above according to the present embodiment will now be described.

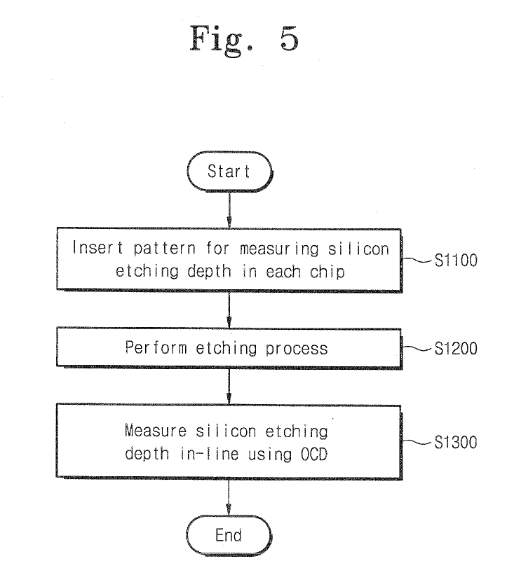

FIG. 5 is a flow chart of a method for measuring a silicon etching depth according to an embodiment. To measure the silicon etching depth, the test pattern 20 illustrated in FIGS. 1, 3 and 4 is used.

Referring to FIG. 5, in the method for measuring the silicon etching depth accordlng to the present embodiment, the test pattern 20 is may be inserted in each semiconductor chip 10 (S1100). The test pattern 20 may be preferably inserted in an edge region of each semiconductor chip 10.

Then, an etching process for forming contact holes 16 and 26 is performed (S1200). In the etching process (S1200), contact holes 16 for actual cells and test contact holes 26 for a test are formed on the semiconductor chip 10. The number of test contact holes 26 formed in each test pattern 20 may be controlled with regard to the test time and productivity.

As illustrated in FIGS. 2 and 3, although having different structures, the contact holes 16 for the actual cells and the test contact holes 26 are formed under the same environment through the same process. Thus, a result of measuring the silicon etching depth with respect to the test contact hole 26 coincides with a result of measuring the silicon etching depth with respect to the contact holes 16 for actual cells. Accordingly, in the present embodiment, the silicon etching depth is measured using the test contact hole 26 that has a simple structure and is suitable for measuring an OCD (S1300), without measuring the silicon etching depth with respect to the contact holes 16 that has a complicated structure and is not suitable for measuring the OCD. The OCD using the test contact hole 26 may be measured in-line and in real time during a semiconductor manufacturing process performed on a wafer. Then, distribution of silicon etching depths in the wafer 100 having the semiconductor chips may be analyzed on the basis of the measured OCD. Consequently, etching parameters for wafers being processed can be controlled in real time.

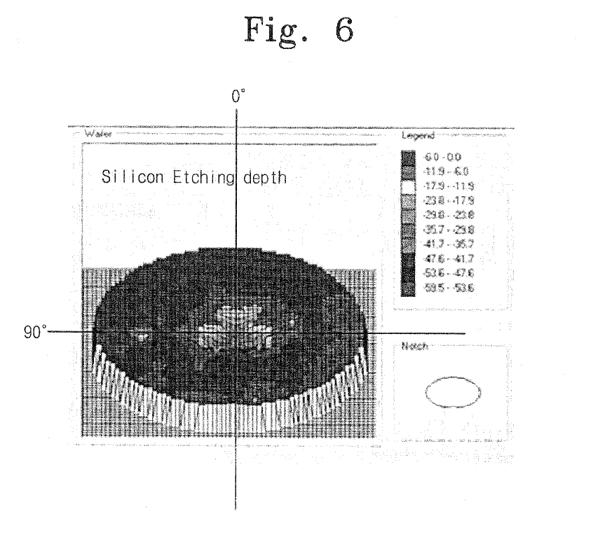

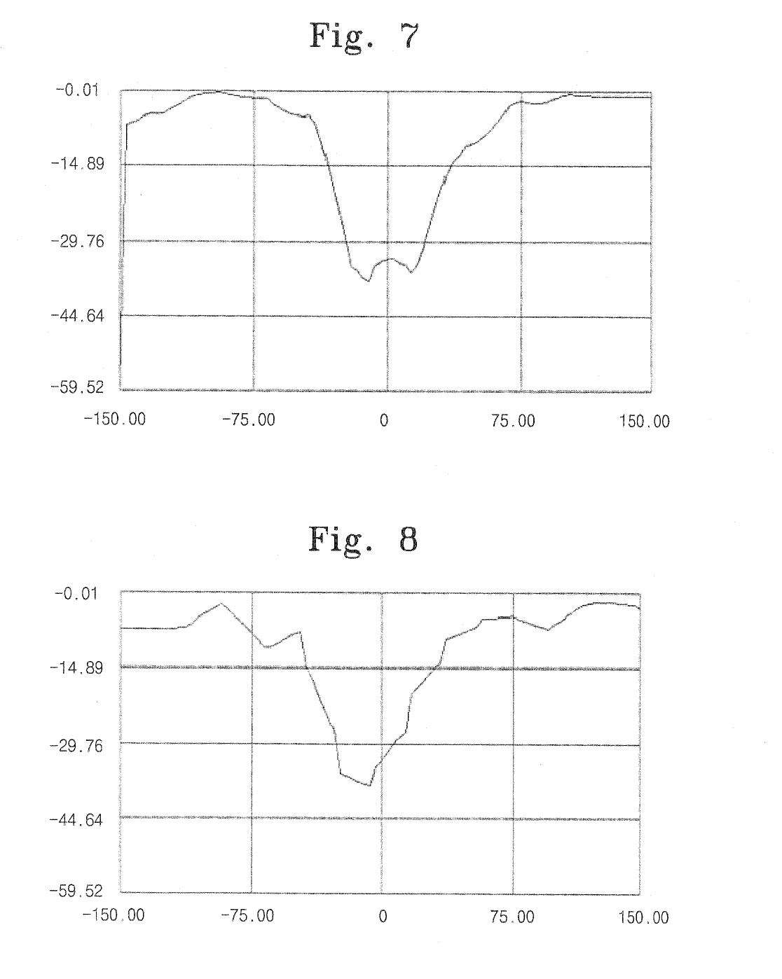

FIGS. 6 through 8 are graphs showing results from an analysis of the silicon etching depth of the test contact hole 26 measured after the contact-hole forming process (i.e., an etching process). FIG. 6 is a graph showing a three-dimensional distribution of silicon etching depths of the test contact hole 26 within the wafer 100. FIG. 7 is a graph showing the two-dimensional distribution of the silicon etching depths of the test contact hole 26 shown in FIG. 6 along the zero-degree axis. FIG. 8 is a graph showing the two-dimensional distribution of the silicon etching depths of the test contact hole 26 shown in FIG. 6 along the 90-degree axis.

Referring to FIGS. 6 through 8, after the etching process for forming the contact holes 16 and 26, the distribution of the silicon etching depths of the test contact hole 26 may be analyzed in various manners. The distribution of the silicon etching depths may be measured in-line by measuring the OCD in real time. Thus, etching parameters with respect to wafers being processed can be controlled in real time. The controlled etching parameters may be immediately applied to a contact-hole forming process of the wafer to be processed next. Consequently, the silicon etching depth is accurately controlled, so that any defects occurring in the contact-hole forming process can be minimized.

According to the present embodiment, a silicon etching depth may be monitored in-line and in real time after the contact process. Accordingly, defects in a contact process are minimized, and thus a yield is improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method for measuring a silicon etching depth, the method comprising:
performing a contact-hole forming process with respect to a plurality of semiconductor chips, each including a test pattern;
measuring an OCD (optical critical dimension) from the test pattern; and
analyzing a distribution of silicon etching depths of a wafer including the semiconductor chips on the basis of the measured OCD.

2. The method of claim 1, further comprising controlling etching conditions for the contact-hole forming process responsive to the analyzed distribution of the silicon etching depths.

3. The method of claim 1, wherein the test pattern is a TEG (test element group) designated to one region of each semiconductor chip.

4. The method of claim 1, wherein the contact-hole forming process is performed so that a first type contact hole for an actual cell, and one or more second type contact holes for the test pattern are formed in each of the semiconductor chips.

5. The method of claim 4, wherein each of the second type contact holes have the same diameter.

6. The method of claim 4, wherein the second type contact hole is spaced apart from another adjacent second type contact hole by a first distance, and the second type contact hole is spaced apart from an adjacent first type contact hole by the first distance.

7. The method of claim 4, wherein the test pattern has a ratio given by 0.5<c/a<3, where c represents a diameter of the second type contact hole, and a represents a distance between first or second type contact holes that are adjacent to each other.

8. The method of claim 4, wherein the OCD is measured from the second type contact hole.

9. The method of claim 8, wherein the OCD comprises a diameter of the second type contact hole, a thickness of an oxide formed at a side of the second type contact hole, and an etching depth of silicon etched at a lower side of the contact hole.

10. The method of claim 8, wherein the OCD measured from the second type contact hole coincides with an OCD of the first type contact hole.

11. The method of claim 1, further comprising measuring the OCD in-line with process line equipment.

12. The method of claim 1, wherein the step of analyzing the distribution of the silicon etching depths is performed in real time.

13. A test pattern for measuring a silicon etching depth, comprising:
a first region in which a first type contact hole for an actual cell is formed by a contact-hole forming process; and
a second region in which a second type contact hole is formed by the contact-hole forming process,
wherein, the second type contact hole has a simpler structure than the first type contact hole, the simpler structure of the second type contact hole adapted to an OCD (optical critical dimension) measurement, and wherein critical dimensions of the first type contact hole coincide with the OCD measurement of the second type contact hole.

14. The test pattern of claim 13, wherein the second region is a TEG (test element group) for testing characteristics of the first type contact hole.

15. The test pattern of claim 13, wherein a plurality of the second type contact holes each have the same diameter.

16. The test pattern of claim 13, wherein the second type contact hole is spaced apart from another adjacent second type contact hole by a first distance, and the second type contact hole is spaced apart from an adjacent first type contact hole by the first distance.

17. The test pattern of claim 13, wherein the test pattern has a ratio determined by 0.5<c/a<3, where c represents a diameter of the second type contact hole, and a represents a distance between first or second type contact holes that are adjacent to each other.

18. The test pattern of claim 13, wherein the OCD measurement comprises a measurement of a diameter of the second type contact hole, a thickness of an oxide formed at a side of the second type contact hole, and an etching depth of silicon etched at a lower portion of the contact hole.

19. The test pattern of claim 13, wherein the OCD is adapted to measuring in-line with manufacturing line equipment.

20. The test pattern of claim 13, wherein the second type contact hole has a cylindrical or conical shape with smooth and continuous sidewalls.
